(19) United States
(12) Patent Application Publication
(10) Pub. No.: US 2007/0012557 A1
(43) Pub. Date: Jan. 18, 2007

(54) Low voltage sputtering for large area substrates

(75) Inventors: Akihiro Hosokawa, Cupertino, CA (US); Hien Minh H. Le, San Jose, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC

(21) Appl. No.: 11/181,043

(22) Filed: Jul. 13, 2005

(51) Int. Cl. C23C 14/32; C23C 14/00

(52) U.S. Cl. 204/192.1; 204/298.16

(57) ABSTRACT

Embodiments of the present invention generally relate to sputtering of materials. In particular, the invention relates to sputtering voltage used during physical vapor deposition of large area substrates to prevent arcing. One embodiment of the invention describes an apparatus for sputtering materials on rectangular substrates at a voltage less than 400 volts, that comprises a sputtering target; wherein the target is biased at a voltage less than 400 volts during sputtering materials on the rectangular substrates, a grounded shield surrounding the sputtering target, wherein the shortest distance between the grounded shield and the sputtering target is less than the plasma dark space thickness, a magnetron in the back of the sputtering target, where in the edge of the magnetron does not overlap the grounded shield, and an antenna structure placed between the sputtering target and the substrate, wherein the antenna structure is grounded during sputtering.

### BACKGROUND OF THE INVENTION

1. Field of the Invention

Embodiments of the present invention generally relate to sputtering of materials. In particular, the invention relates to sputtering voltage used during physical vapor deposition of large area substrates.

2. Description of the Related Art

Physical vapor deposition (PVD) is one of the most commonly used processes in fabrication of electronic devices, such as flat panel displays. PVD is a plasma process performed in a vacuum chamber where a negatively biased target is exposed to a plasma of an inert gas having relatively heavy atoms (e.g., argon) or a gas mixture comprising such inert gas. Bombardment (or sputtering) of the target by ions of the inert gas results in ejection of atoms of the target material. The ejected atoms accumulate as a deposited film on a substrate placed on a substrate pedestal disposed underneath the target within the chamber. Flat panel display sputtering is principally distinguished from the long developed technology of wafer sputtering by the large size of the substrates and their rectangular shape.

DC magnetron sputtering is a principal method of depositing metal onto a semiconductor integrated circuit during its fabrication in order to form electrical connections and other structures in the integrated circuit. A magnetron having at least a pair of opposed magnetic poles is disposed in back of the target to generate a magnetic field close to and parallel to the front face of the target. The magnetic field traps electrons, and, for charge neutrality in the plasma, additional argon ions are attracted into the region adjacent to the magnetron to form there a high-density plasma. Thereby, the sputtering rate is increased. Usually, the sides of the sputter reactor are covered with a shield to protect the chamber walls from sputter deposition. The shield is typically electrically grounded and thus provides an anode in opposition to the target cathode to capacitively couple the DC target power into the chamber and its plasma. In some sputtering chambers, there is a dark space shield spaced sufficiently close to the target so as to inhibit the formation of plasma between the target and the shield which could permit an electrical short to develop between the shield and the target. The metallic target is often biased to a negative DC bias in the range of about −400 to −600 volts DC to attract positive ions of the argon working gas toward the target to sputter the metal atoms.

In the early 1990's, sputter reactors were developed for thin film transistor (TFT) circuits formed on glass panels to be used for large displays, such as liquid crystal displays (LCDs) for use as computer monitors or television screens. The technology was later applied to other types of displays, such as plasma displays and organic semiconductors, and on other panel compositions, such as plastic and polymer. Some of the early reactors were designed for panels having a size of about 400 mm×600 mm. It was generally considered infeasible to form such large targets with a single continuous sputter layer. Instead, multiple tiles of sputtering materials are bonded to a single target backing plate. For some flat panel targets, the tiles could be made big enough to extend across the short direction of the target so that the tiles form a one-dimensional array on the backing plate.

The tiles are typically bonded to a backing plate with a gap possibly formed between the tiles. Neighboring tiles may directly abut but should not force each other. On the other hand, the width of the gap between the tiles should be no more than the plasma dark space, which generally corresponds to the plasma sheath thickness and is generally slightly greater than about 0.5 mm to 1 mm for the usual pressures of argon working gas. Plasmas cannot form in spaces having minimum distances of less than the plasma dark space. If the gap is only slightly larger than the plasma dark space, the plasma state in the gap may be unsteady and could result in intermittent arcing. Even if the arcing is confined to tile material, the arc is likely to ablate particles of the target material rather than atoms and create contaminant particles. If the plasma reaches the backing plate, it will be sputtered. Plate sputtering will introduce material contamination if the tiles and backing plate are of different materials. Furthermore, plate sputtering will make it difficult to reuse the backing plate for a refurbished target.

Arcing is a serious concern for a multi-tile target and is more likely to occur when the sputtering voltage is high. Therefore, a need exists in the art for an apparatus and a method of sputtering targets at low voltage for large area substrate processing system.

### SUMMARY OF THE INVENTION

Embodiments of the present invention generally relate to sputtering of materials. In particular, the invention relates to sputtering voltage used during physical vapor deposition of large area substrates to prevent arcing.

In one embodiment, an apparatus for sputtering materials on rectangular substrates at a voltage less than 400 volts comprises a sputtering target; wherein the target is biased at a voltage less than 400 volts during sputtering materials on the rectangular substrates, a grounded shield surrounding the sputtering target, wherein the shortest distance between the grounded shield and the sputtering target is less than the plasma dark space thickness, and a magnetron in the back of the sputtering target, wherein the edge of the magnetron does not overlap the grounded shield.

In another embodiment, an apparatus for sputtering materials on rectangular substrates at a voltage less than 400 volts comprises a sputtering target; wherein the target is biased at a voltage less than 400 volts during sputtering materials on the rectangular substrates, a grounded shield surrounding the sputtering target, wherein the shortest distance between the grounded shield and the sputtering target is less than the plasma dark space thickness, a magnetron in the back of the sputtering target, where in the edge of the magnetron does not overlap the grounded shield, and an antenna structure placed between the sputtering target and the substrate, wherein the antenna structure is grounded during sputtering.

In another embodiment, a method of sputtering materials at a voltage less than 400 volts on a rectangular substrate comprises placing the rectangular substrate in a sputtering chamber that has a sputtering target, a grounded shield surrounding the sputtering target, wherein the shortest distance between the grounded shield and the sputtering target is less than the plasma dark space thickness, a magnetron in the back of the sputtering target, wherein the edge of the magnetron does not overlap the grounded shield, and an antenna structure placed between the sputtering target and the substrate, wherein the antenna structure is grounded during sputtering, igniting plasma at a first voltage, and sputtering materials on the rectangular substrate at a second voltage that is less than 400 volts.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a simplified cross-sectional view of a plasma sputter reactor for large area substrates.

FIG. 1B shows a plan view of a target formed from 17 target tiles.

FIG. 1C shows a plan view of a target formed from 6 target tiles.

FIG. 1D shows a plan view of a target formed from 3 target tiles.

FIG. 1E is a schematic detail of the interface between the ground shield, target, and chamber body of a PVD chamber of FIG. 1A.

FIG. 2A is a plan view of a rectangularized spiral magnetron.

FIG. 2B is an elevational view of a linear scan mechanism having the magnetron slidably supported on the target.

FIG. 2C shows a sputtering process flow.

FIG. 3A (prior art) is a cross-sectional view of a conventional PVD chamber for wafers.

FIG. 3B (prior art) is a top view of sputtering target, magnetron, and dark space shield of a conventional PVD chamber of FIG. 3A.

FIG. 3C is a top view of sputtering target, magnetron, and shield of a PVD chamber for large area substrates of FIG. 1A.

FIG. 4 is schematic cross-sectional view of a PVD chamber for large area substrates with exemplary electrons near the center and edge of the target.

FIG. 5A is a top view of an exemplary antenna.

FIG. 5B is a schematic cross-sectional view of the PVD chamber for large area substrates with an antenna structure.

### DETAILED DESCRIPTION

Embodiments of the invention describe an apparatus and a method of sputtering targets at low sputtering voltage for large area substrate systems.

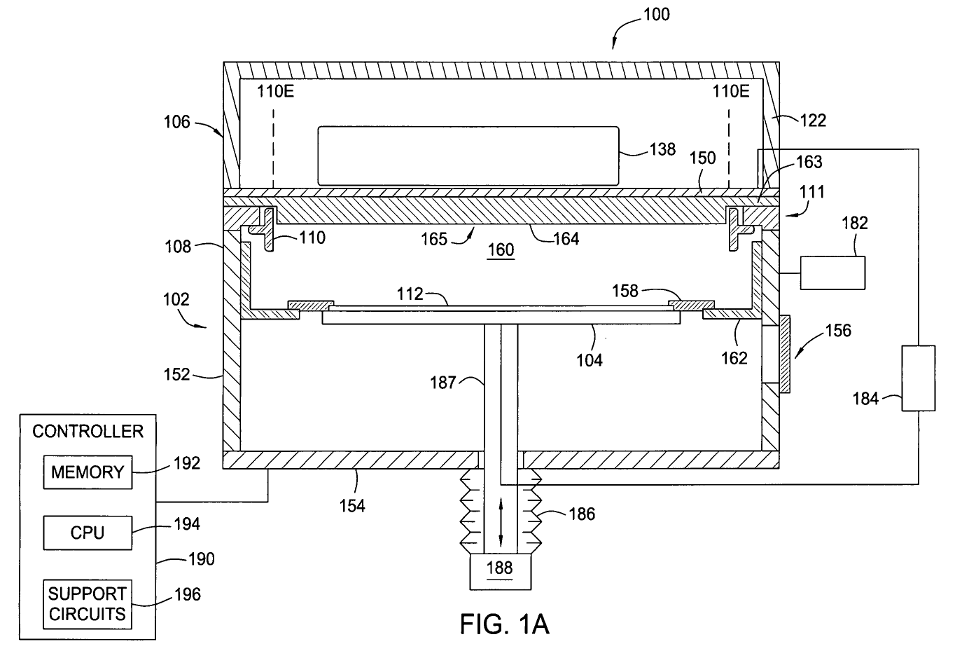

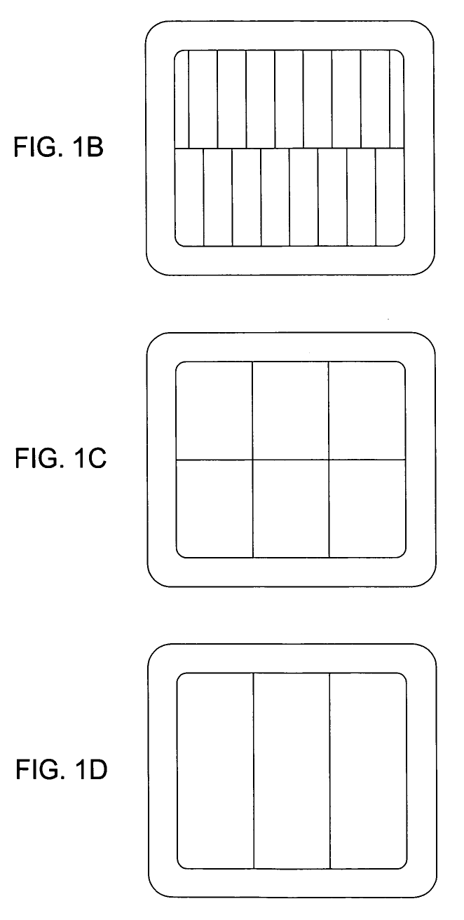

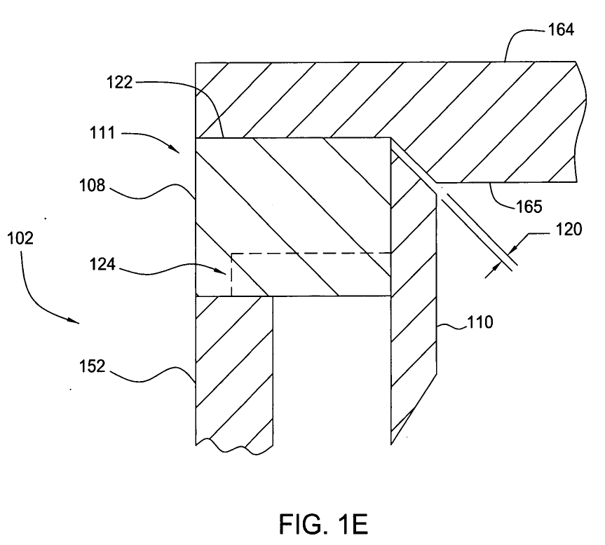

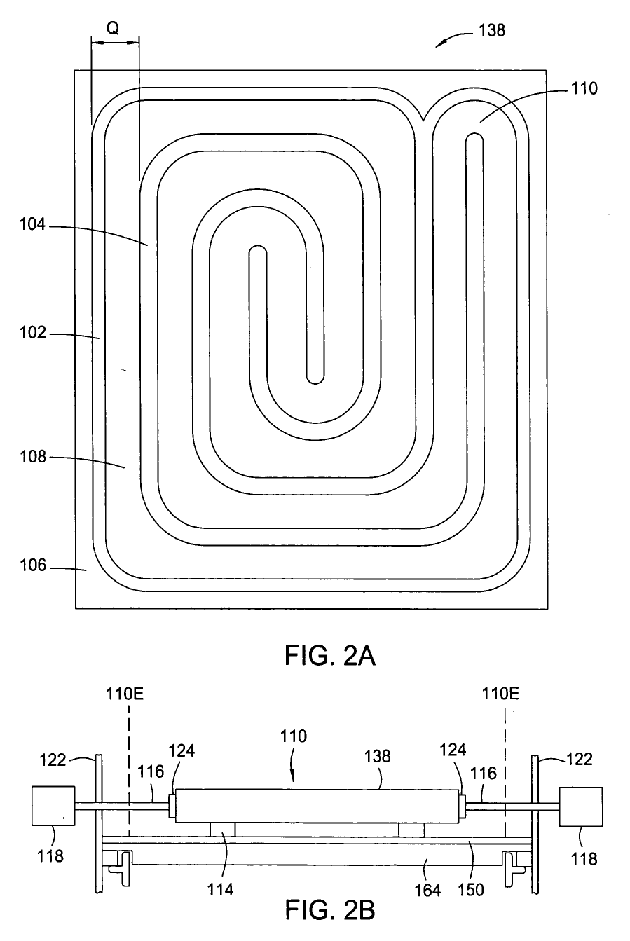

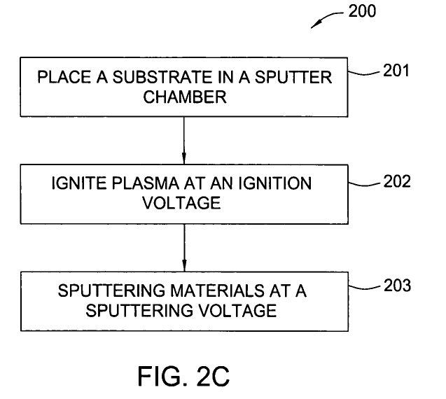

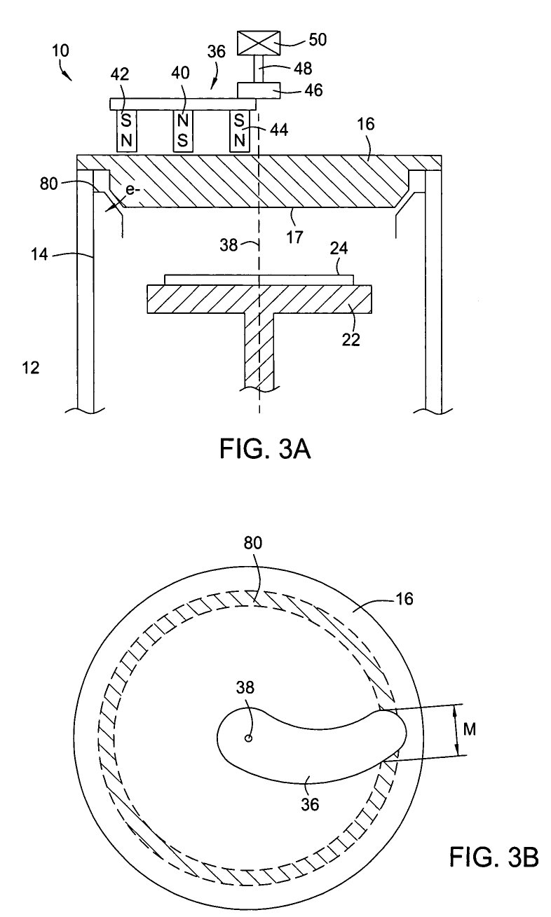

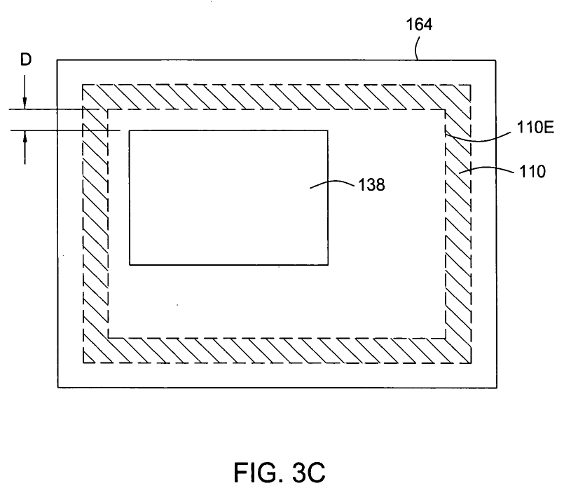

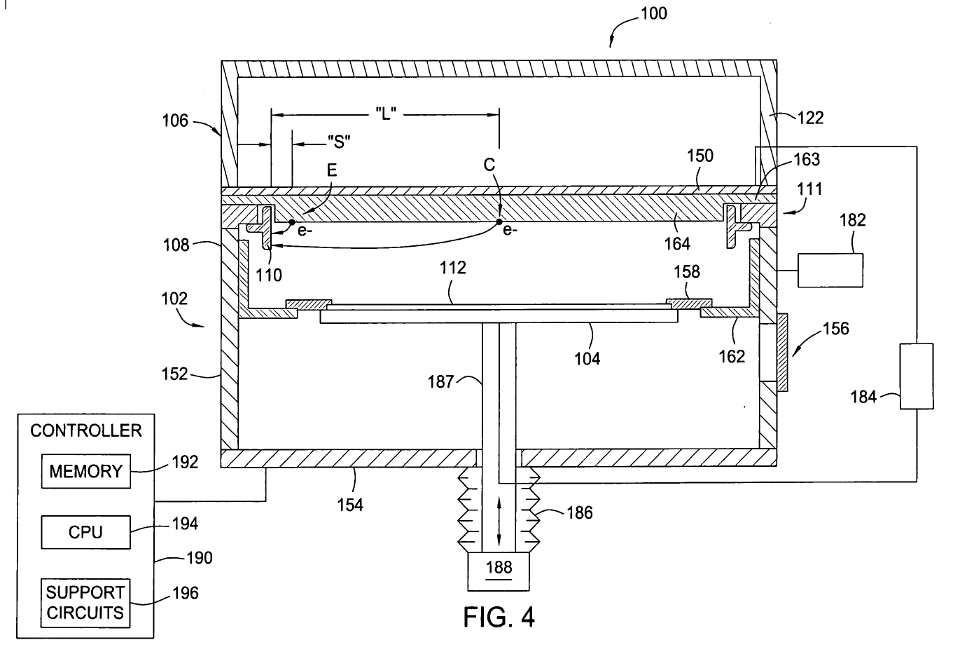

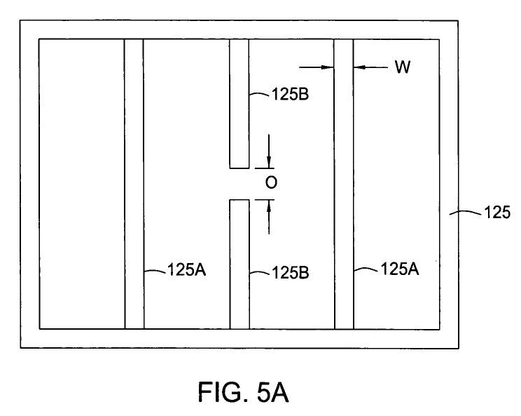

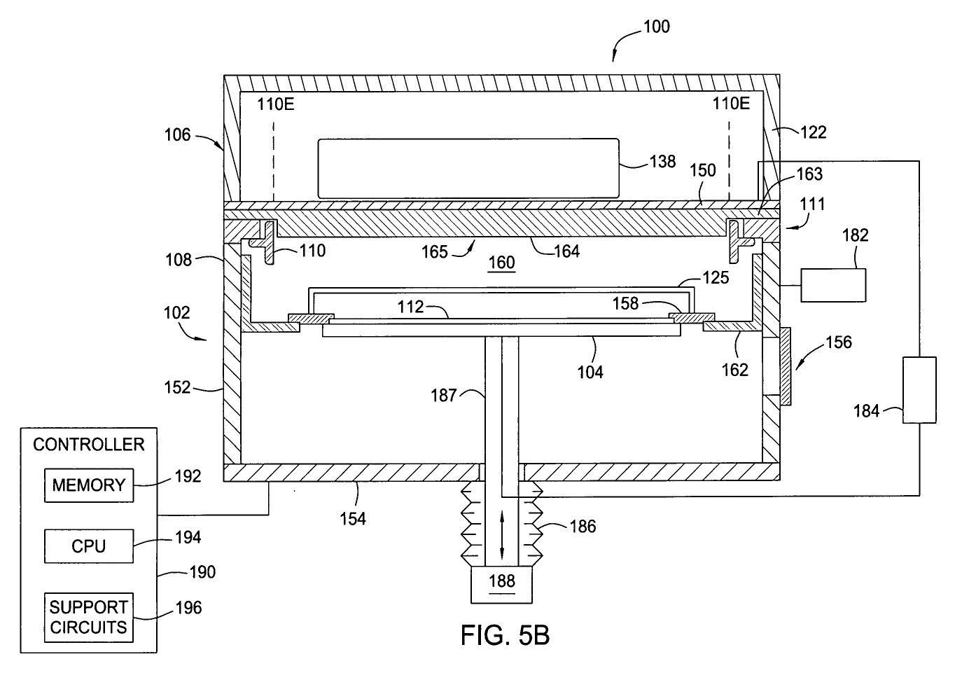

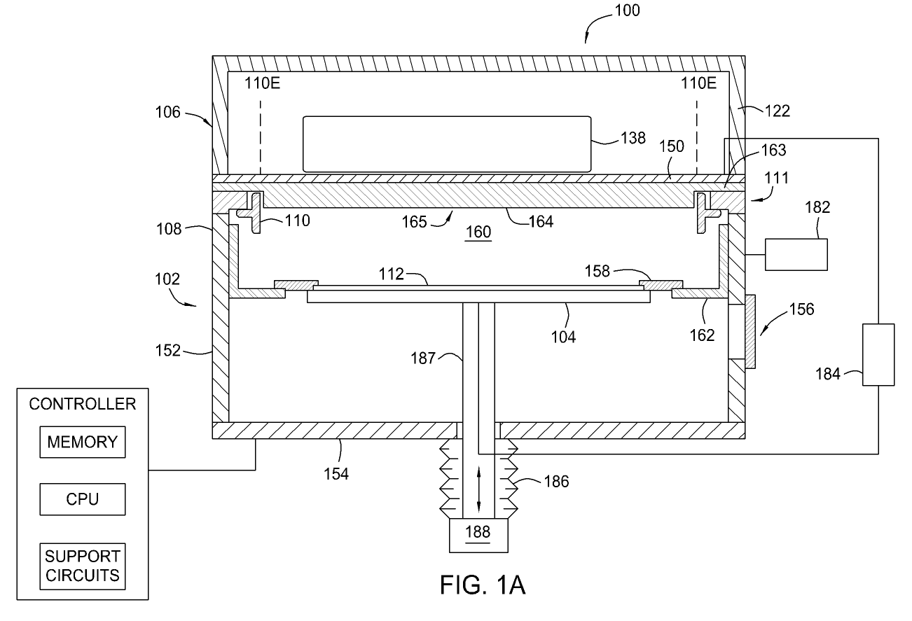

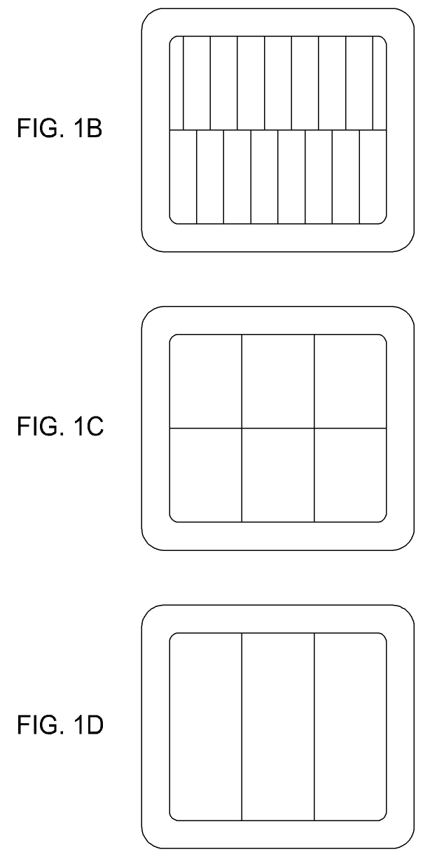

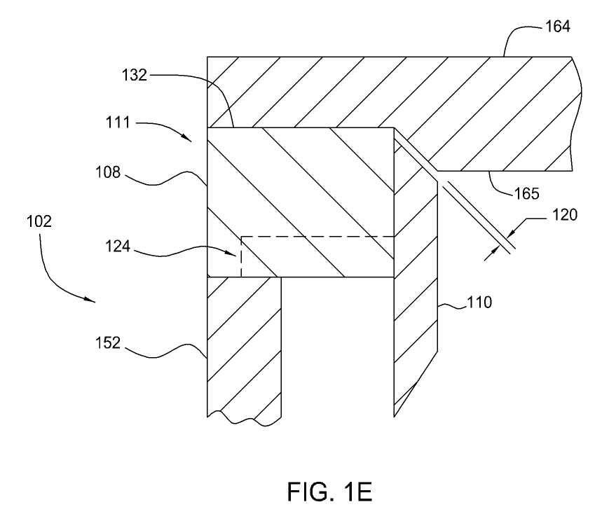

FIG. 1A depicts a process chamber 100 that includes one embodiment of a ground shield assembly 111 of the present invention. One example of a process chamber 100 that may be adapted to benefit from the invention is a PVD process chamber, available from AKT, Inc., located in Santa Clara, Calif.

The exemplary process chamber 100 includes a chamber body 102 and a lid assembly 106 that define an evacuable process volume 160. The chamber body 102 is typically fabricated from welded stainless steel plates or a unitary block of aluminum. The chamber body 102 generally includes sidewalls 152 and a bottom 154. The sidewalls 152 and/or bottom 154 generally contain a plurality of apertures that include an access port 156 and a pumping port (not shown). Other apertures, such as a shutter disk port (not shown) may also optionally be formed in the sidewalls 152 and or bottom 154 of the chamber body 102. The sealable access port 156 provides for entrance and egress of a substrate 112 to and from the process chamber 100. The pumping port is coupled to a pumping system (also not shown) that evacuates and controls the pressure within the process volume 160.

A substrate support 104 is generally disposed on the bottom 154 of the chamber body 102 and supports the substrate 112 thereupon during processing. The substrate support 104 is typically fabricated from aluminum, stainless steel, ceramic or combinations thereof. A shaft 187 extends through the bottom 154 of the chamber 102 and couples the substrate support 104 to a lift mechanism 188. The lift mechanism 188 is configured to move the substrate support 104 between a lower position and an upper position. The substrate support 104 is depicted in an intermediate position in FIG. 1A. A bellows 186 is typically disposed between the substrate support 104 and the chamber bottom 154 and provides a flexible seal therebetween, thereby maintaining vacuum integrity of the chamber volume 160. A sputtering gas, typically argon, is supplied into the vacuum chamber 160 at a pressure in the mTorr range.

Optionally, a bracket 162 and a shadow frame 158 may be disposed within the chamber body 102. The bracket 162 may be coupled, for example, to the wall 152 of the chamber body 102. The shadow frame 158 is generally configured to confine deposition of the sputtered material to a portion of the substrate 112 exposed through the center of the shadow frame 158. When the substrate support 104 is moved to the upper position for processing, an outer edge of the substrate 112 disposed on the substrate support 104 engages the shadow frame 158 and lifts the shadow frame 158 from the bracket 162. Alternatively, shadow frames having other configurations may optionally be utilized as well.

The substrate support 104 is moved into the lower position for loading and unloading a substrate from the substrate support 104. In the lower position, the substrate support 104 is positioned below the shield 162 and the port 156. The substrate 112 may then be removed from or placed into the chamber 100 through the port 156 in the sidewall 152 while clearing the shadow frame 158 and shield 162. Lift pins (not shown) are selectively moved through the substrate support 104 to space the substrate 112 away from the substrate support 104 to facilitate the placement or removal of the substrate 112 by a wafer transfer mechanism disposed exterior to the process chamber 100 such as a single blade robot (not shown).

The lid assembly 106 generally includes a target 164 and the ground shield assembly 111 directly coupled thereto. The target 164 provides material that is deposited on the substrate 112 during the PVD process. The target 164 may be bonded to a backing plate 150, which could provide mechanical support and target cooling mechanism. This backing plate 150 is more complex than the usual backing plate for wafer processing since, for the very large panel size, it is desired to provide a backside vacuum chamber in addition to the usual cooling bath so as to minimize the differential pressure across the very large target 164. The target could be made of any type of sputtering materials, such as aluminum, copper, gold, nickel, tin, molybdenum, chromium, zinc, palladium, stainless steel, palladium alloys, tin alloy, aluminum alloy, copper alloy, and indium tin oxide (ITO).

The target generally includes a peripheral portion 163 and a central portion 165. The peripheral portion 163 is disposed over the walls 152 of the chamber. The central portion 165 of the target 164 may protrude, or extend in a direction towards the substrate support 104. It is contemplated that other target configurations may be utilized as well. The target material may also comprise adjacent tiles or segments of material that together form the target. FIGS. 1B, 1C and 1D shows three exemplary arrangement of multiple tiles on the targets. FIG. 1B has 17 tiles; FIG. 1C has 6 tiles; while FIG. 1D has 3 tiles. The target 164 and substrate support 104 are biased relative to each other by a power source 184. A gas, such as argon, is supplied to the process volume 160 from a gas source 182 through one or more apertures (not shown), typically formed in the walls 152 of the process chamber 100. A plasma is formed from the gas between the substrate 112 and the target 164. Ions within the plasma are accelerated toward the target 164 and cause material to become dislodged from the target 164. The dislodged material is attracted towards the substrate 112 and deposits a film of material thereon.

The ground shield assembly 111 includes a ground frame 108 and a ground shield 110. The ground shield surrounds the central portion 165 of the target 164 to define a processing region within the process volume 160 and is coupled to the peripheral portion 163 of the target 164 by the ground frame 108. The ground frame 108 electrically insulates the ground shield 110 from the target 164 while providing a ground path to the body 102 of the chamber 100 (typically through the sidewalls 152).

The ground shield 110 constrains the plasma within the region circumscribed by the ground shield 110 to ensure that material is only dislodged from the central portion 165 of the target 164. The ground shield 110 may also facilitate depositing the dislodged target material mainly on the substrate 112. This maximizes the efficient use of the target material as well as protects other regions of the chamber body 102 from deposition or attack from the dislodged species or the from the plasma, thereby enhancing chamber longevity and reducing the downtime and cost required to clean or otherwise maintain the chamber. Another benefit derived from this aspect of the invention is the reduction of particles that may become dislodged from the chamber body 102 (for example, due to flaking of deposited films or attack of the chamber body 102 from the plasma) and re-deposited upon the surface of the substrate 112, thereby improving product quality and yield.

FIG. 1E depicts a schematic detail of the interface between an exemplary ground frame 108 and an exemplary ground shield 110 of the ground shield assembly 111, the target 164, and the chamber body 152. The ground frame 108 is generally coupled to the target 164. Alternatively, the ground frame 108 may be coupled to a backing plate (not shown), or other component, of the lid assembly 106 so long as the ground shield 110 may be positioned and adjusted as necessary with respect to the target 164. The ground frame 108 generally insulates the ground shield 110 from the target 164. In one embodiment, the ground frame 108 has an insulative interface 122 with the target 164.

The ground frame 108 also provides a conductive path 124 from the ground shield 110 to the chamber body 102. In one embodiment, the ground frame 108 has a conductive path 124 to the sidewall 152 of the body 102. The conductive path 124 may comprise a conductive wire, lead, strap, and the like coupled between the ground shield 110 and the body 102. Alternatively, the ground frame 108 may have a lower portion comprised of a suitable electrically conductive material to provide the conductive path 124 between the ground shield 110 and the body 102.

The ground shield 110 is coupled to the ground frame 108 in a suitable manner for adjusting and maintaining a gap 120 between the central portion 165 of the target 164 and the ground shield 110. The gap 120 is generally uniform in depth and along its length, i.e., the opposing faces of the target 164 and the ground shield 110 that form the gap are generally parallel. As such, an upper edge of the ground shield 110 is generally formed to be parallel with the mating face of a protruding edge of the central portion 165 of the target 164. It should be noted that the angles of the respective edges of the ground shield 110 and the target 164 depicted in FIG. 1A (vertical or 90 degrees) and FIG. 1E (about 45 degrees) are for illustrative purposes only, and any other suitable angle may be used as well. In addition, the ground shield 110 may have means for adjusting the width of the gap 120 along its length as well. The gap 120 may generally be any width wide enough to prevent arcing between the target 164 and the ground shield 110 and less than the plasma dark space thickness to maintain the dark space of the plasma between the target 164 and the ground shield 110, e.g., to prevent the glow discharge of the plasma from moving into the gap 120. Details of the ground shield are described in commonly assigned U.S. application Ser. No. 11/131,009, titled “Ground Shield for a PVD Chamber”, filed on May 16, 2005.

The lid assembly 106 further comprises a magnetron 138, which enhances consumption of the target material during processing. The magnetron 138 can be scanned in two orthogonal dimensions over the rectangular target 164 to increase the sputtering uniformity. In one embodiment, the magnetron comprises an inner pole having a first magnetic polarity perpendicular to a plane, extending along a single two-ended path in said plane, and including a plurality of straight portions at least some of which separately extend along one rectangular coordinate in a convolute pattern, and an outer pole having a second magnetic polarity opposite said first magnetic polarity, surrounding said inner pole, and separated therefrom by a separation.

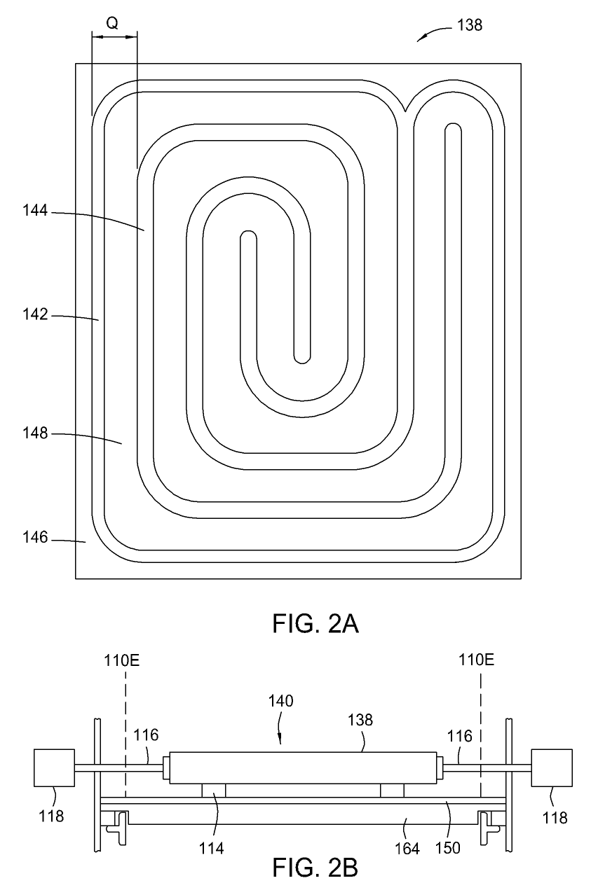

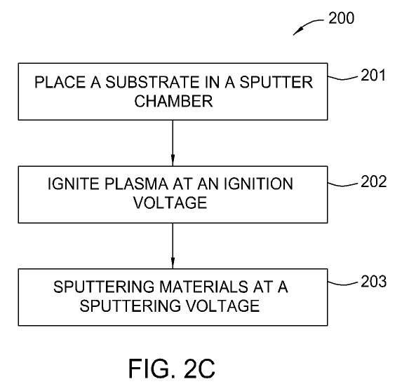

FIG. 2A shows an exemplary magnetron 138 illustrated in plan view. The magnetron 138 is a rectangularized spiral magnetron that includes continuous grooves 102, 104 formed in a magnetron plate 106. Unillustrated cylindrical magnets of opposed polarities respectively fill the two grooves 102, 104. The groove 102 completely surrounds the groove 104. The two grooves 102, 104 are arranged on a track pitch Q and are separated from each other by a mesa 108 of substantially constant width. In the context of the previous descriptions the mesa 108 represents the gap between the opposed poles. The one groove 102 represents the outer pole. The other groove 104 represents the inner pole which is surrounded by the outer pole. Similarly to the racetrack magnetron, whether twisted or not, one magnetic pole represented by the groove 104 is completely surrounded by the other magnetic pole represented by the groove 102, thereby intensifying the magnetic field and forming one or more plasma loops to prevent end loss. The width of the outermost portions of the groove 102 is only slightly more than half the widths of the inner portions of that groove 102 and of all the portions of the other groove 104 since the outermost portions accommodate only a single row of magnets while the other groove portions accommodate two rows in staggered arrangements.

Other convolute shapes for the magnetron are possible. For example, serpentine and spiral magnetrons can be combined in different ways. A spiral magnetron may be joined to a serpentine magnetron, both being formed with a single plasma loop. Two spiral magnetrons may be joined together, for example, with opposite twists. Two spiral magnetrons may bracket a serpentine magnetron. Again, a single plasma loop is desirable. However, multiple convolute plasma loops enjoy some advantages of the invention.

As mentioned earlier, sputtering uniformity can be increased by scanning a convoluted magnetron in two orthogonal dimensions over a rectangular target. The scanning mechanism can assume different forms. In a scanning mechanism 140 illustrated in FIG. 2B, a magnetron plate 138, including the magnets through a plurality of insulating pads 114 or bearings held in holes at the bottom of the magnetron plate 138, is placed on the backing plate 150, which is attached to the target 164. The pads 114 may be composed of Teflon and have a diameter of 5 cm and protrude from the magnetron plate 112 by 2 mm. Opposed pusher rods 116 driven by external drive sources 118 penetrate the vacuum sealed back wall 122 to push the magnetron plate 138 in opposite directions. The motive sources 118 typically are bidirectional rotary motors driving a drive shaft having a rotary seal to the back wall 122. A lead screw mechanism inside the back wall 122 converts the rotary motion to linear motion. Two perpendicularly arranged pairs of pusher rods 116 and motive sources 118 provide independent two-dimensional scanning. A single pair of pusher rods 116 and motive sources aligned along the target diagonal provide coupled two-dimensional scanning relative to the sides of the target. Details of the magnetron and the scanning of the magnetron are described in U.S. application Ser. No. 10/863,152, titled “Two Dimensional Magnetron Scanning for Flat Panel Sputtering”, filed on Jun. 7, 2004.

FIG. 2C shows a process flow of sputtering materials on substrates. The sputtering process 200 starts by placing a substrate in a sputtering chamber at step 201. Afterwards, plasma is ignited at an ignition voltage at step 202. Once the plasma is ignited, the materials are sputtered at a sputtering voltage at step 203. Ignition voltage is higher than the sputtering voltage.

As described earlier, conventional sputtering process uses over 1000 volts to ignite plasma and uses 400-600 volts during deposition. For multi-tiles target sputtering, 400-600 volts sputtering voltage is too high, since it could result in arcing. Experiments with multi-tile targets show that arcing occurs at around 400 volts plasma voltage. Therefore, it's desirable to keep sputtering voltage below 400 volts, preferably below 375 volts, and most preferably equaling to or below 350 volts.

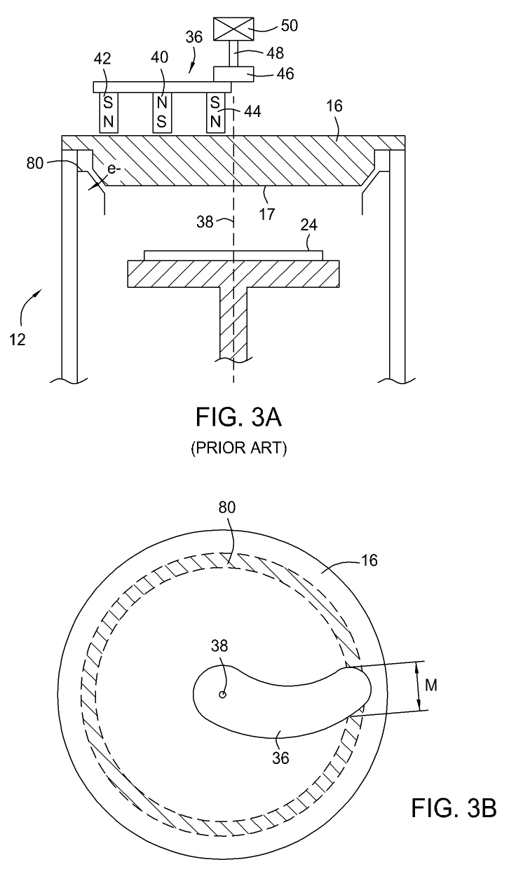

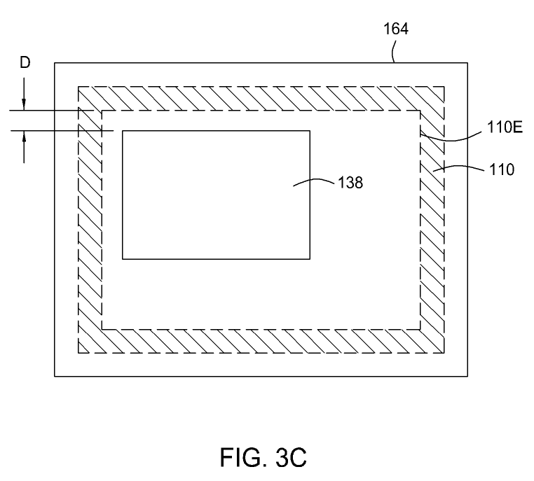

FIG. 3A (prior art) shows an exemplary conventional sputtering system for wafers. In this chamber, a small nested magnetron 36 is supported on an un-illustrated back plate behind the target 16. The chamber 12 and target 16 are generally circularly symmetric about a central axis 38. The magnetron 36 includes an inner magnet pole 40 of a first vertical magnetic polarity and a surrounding outer magnet pole 42 of the opposed second vertical magnetic polarity. Both poles are supported by and magnetically coupled through a magnetic yoke 44. The yoke 44 is fixed to a rotation arm 46 supported on a rotation shaft 48 extending along the central axis 38. A motor 50 connected to the shaft 48 causes the magnetron 36 to rotate about the central axis 38. There is a dark space shield 80 placed around the central part of the target 16 with the shortest distance to the target 16 less than the plasma dark space to prevent plasma being formed between the target and the shield. For a conventional PVD system for wafers, the center part 17 of the target 16, where sputtering occurs, covers the substrate 24 and the edge of this part 17 extends over the edge of the substrate 24 (also called overhang) by about 40-50 mm. To ensure deposition uniformity at the edge of the substrate 24, the magnet 42 of the magnetron 36 is over the dark space shield 80. As shown in FIG. 3A, magnet 42 is above the dark space shield 80. Since magnets, such as magnet 42 and magnet 40, of the magnetron 36 confine the majority of electrons in the chamber underneath them, a significant number of electrons under magnet 42 escapes into the dark space shield 80 during sputtering process. FIG. 3B (prior art) shows the top view of the target 16, the magnetron 36, the dark space shield 80, and the region “M” where a significant number of electrons escapes into the shield 80. Due to the escape of electrons in the “M” region, the sputtering voltage for conventional wafer sputtering system is raised to between 400-600 volts to maintain sufficient electrons in the process chamber to achieve desired sputtering rate.

In the present invention for the large area substrate sputtering system, the central portion 165 of the target 164 covers the substrate 112, and the edge of central portion 165 could extend over the edge of the substrate 112 by 200 mm or more (or 200 mm or more overhang). Due to larger overhang for the large area substrate sputtering system, the magnetron 138 does not have to cross over the edge line 110E (dotted line) of the shield 110, which also acts as a dark space shield, to ensure deposition uniformity near the edge of the large area substrate as needed for magnetrons of PVD systems for wafers. Therefore, there is little or no electron escaping to the shield 110. FIG. 3C shows the top view of the magnetron 138, the target, the shield 110, and the shield edge lines 110. To ensure little or no electrons escaping to the shield 110, the edge of the magnetron 138 should not cross the edge line 110E of the shield 110 and should be kept preferably at a distance “D” greater than 50 mm from the edge line 110E, and most preferably at a distance “D” greater than 100 mm from the edge line 110E. Since the magnetron is kept at a “safe” distance from the shield 110, the sputtering voltage can be lowered to less than 400 volts, e.g. 350 volts for less, and still have enough electrons in the deposition zone to achieve a deposition rate equaling the conventional PVD systems for wafers. The sputtering voltage for systems to process large area substrates should be kept equaling to or below about 375 volts, preferably equaling to or below about 350 volts, and most preferably equaling to or below 330 volts to prevent arcing. In addition to lowering the sputtering voltage, the plasma ignition voltage can also be lowered from about 1800 volts (for conventional PVD systems for wafers) to below 1000 volts, e.g. 800 volts or less, due to the magnetron 138 being kept at a “safe” distance from the shield 110. The ignition voltage for systems to process large area substrates should be kept equaling to or below about 1000 volts, preferably equaling to or below about 800 volts, and most preferably equaling to or below 600 volts to reduce particle generation. Plasma ignition at higher voltage would generate more particles than plasma ignition at low voltage.

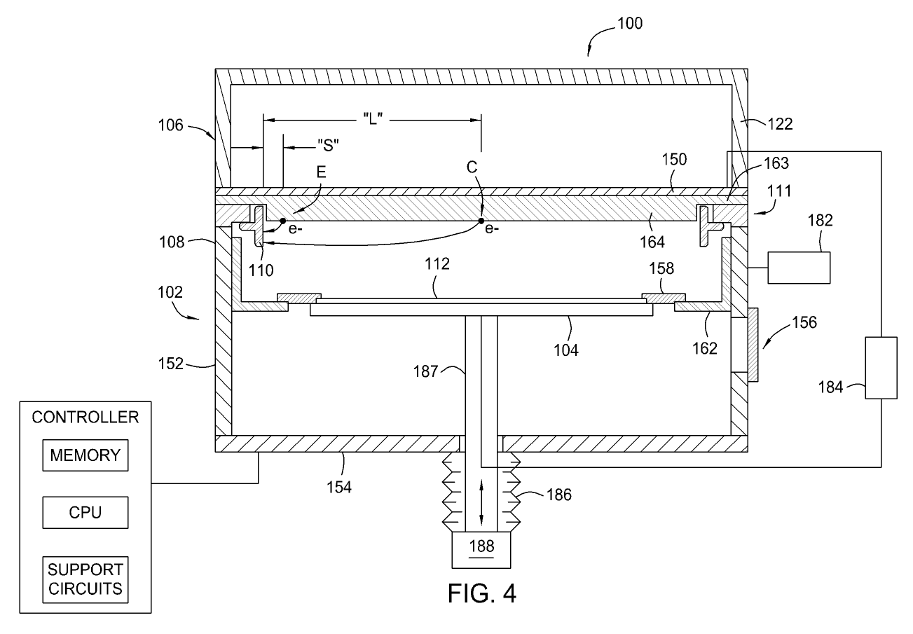

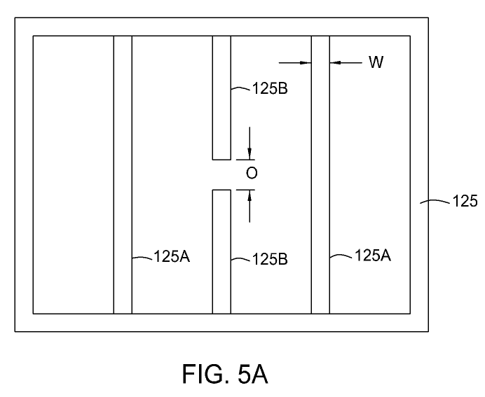

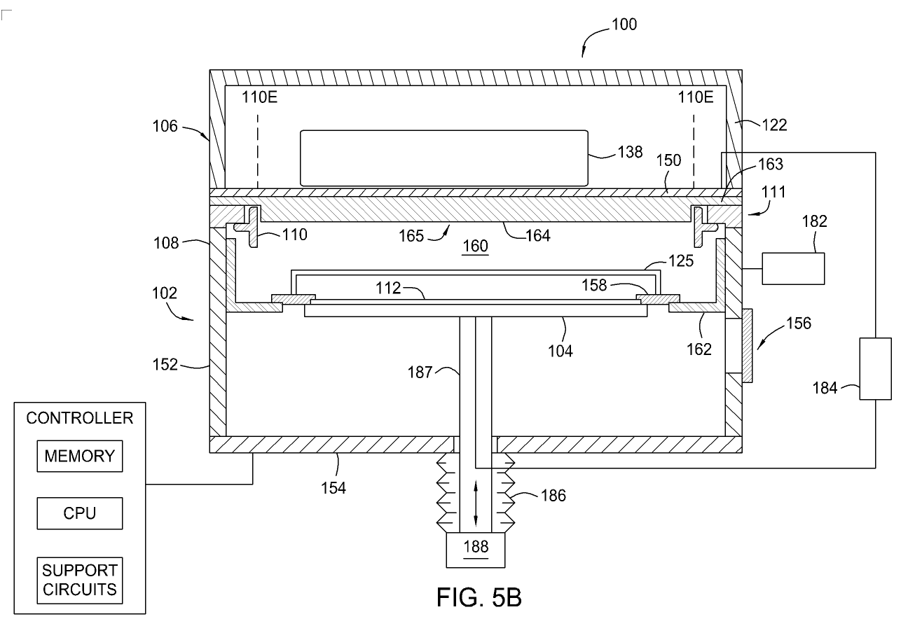

For the large area substrate system, the electron “C” near the center of the substrate needs to travel a long distance “L” to reach grounding shield 110 or grounded chamber wall 152, as shown in FIG. 4. In contrast, the electron “E” near the edge of the substrate only needs to travel a short distance “S” to reach grounding shield 110 or chamber wall 152. If antennas are place between the target and the substrate to provide the grounding path for electrons near the center of the substrate, the sputtering voltage can be further lowered since the resistance is lowered. FIG. 5A shows a top view of an exemplary antenna structure 125 that can be placed on the shadow frame (grounded), be attached to the shield 110 (grounded), or be attached to the chamber wall 152 (grounded) between the target and the substrate. FIG. 5B shows a side view of the antenna structure 125 placed on the shadow frame in the process chamber. Since the electron near the center of the substrate can escape through the grounding path by traveling a shorter distance “Dₛ”, the sputtering voltage can be lowered by about 10-30 volts. The width “w” of the antenna lines 125A, 125B in FIG. 5A is in the range between 5 mm to about 30 mm, and preferably between about 10 mm to about 20 mm. The thickness of the antenna lines 125A, 125B is in the range between about 1 mm to about 10 mm, and preferably between about 3 mm to about 7 mm. The exemplary antenna structure 125 in FIG. 5A has an opening “O” in the central antenna lines 125B. Typically, sputtering deposition is thin in the center of the substrate. By leaving an opening “O” near the center of the substrate (less electrons escaping near the opening “O”), the deposition thickness in the center can be closer to other parts of the substrate. The antenna structure 125 not only can reduce sputtering voltage, but also improve deposition uniformity. The antenna structure 125 in FIG. 5B is just an example. There could be other antenna designs that could achieve similar purposes. For example, there could be more than two 125A lines, e.g. 4, 6, or more, and more than two 125B lines, e.g. 4, 6 or more.

The deposition non-uniformity for 3000 molybdenum ignited at 800 volts and sputtered at 350 volts without the antenna structure 125 is 70%, while the non-uniformity for 3000 molybdenum deposited under the same condition with the antenna structure 125 shown in FIG. 5A is 38%. The results show that the antenna structure 125 improves the deposition uniformity. The non-uniformity is calculated by subtracting the minimum thickness (Tₘᵢₙ) from the maximum thickness (Tₘₐₓ) and divide the result of the subtraction by the sum of maximum thickness and the minimum thickness, or (Tₘₐₓ−Tₘᵢₙ)/(Tₘₐₓ+Tₘᵢₙ).

The concept of the invention can be applied to targets greater than 2000 cm², preferably to targets greater than 15000 cm², and most preferably to targets greater than 40000 cm². The concept of the invention can be applied to single-piece targets or multi-tiles targets.

While the foregoing is directed to embodiments of the present invention, other and further embodiments of the invention may be devised without departing from the basic scope thereof, and the scope thereof is determined by the claims that follow.

1. An apparatus for sputtering materials on rectangular substrates at a voltage less than 400 volts, comprising:
a sputtering target; wherein the target is biased at a voltage less than 400 volts during sputtering materials on the rectangular substrates;
a grounded shield surrounding the sputtering target, wherein the shortest distance between the grounded shield and the sputtering target is less than the plasma dark space thickness; and
a magnetron in the back of the sputtering target, where in the edge of the magnetron does not overlap the grounded shield.

2. The apparatus of claim 1, wherein the target is biased at a voltage equaling to or less than 375 volts during sputtering.

3. The apparatus of claim 2, wherein the target is biased at a voltage equaling to or less than 350 volts during sputtering.

4. The apparatus of claim 1, wherein the plasma ignition voltage is equaling to or less than 1000 volts.

5. The apparatus of claim 4, wherein the plasma ignition voltage is equaling to or less than 800 volts.

6. The apparatus of claim 1, wherein the sputtering target is made of multiple tiles.

7. The apparatus of claim 1, wherein in the surface areas of the rectangular substrates are greater than 15000 cm².

8. The apparatus of claim 1, wherein the magnetron comprises:
an inner pole having a first magnetic polarity perpendicular to a plane, extending along a single two-ended path in said plane, and including a plurality of straight portions at least some of which separately extend along one rectangular coordinate in a convolute pattern; and
an outer pole having a second magnetic polarity opposite said first magnetic polarity, surrounding said inner pole, and separated therefrom by a separation.

9. The apparatus of claim 1, wherein the magnetron is scanned in two orthogonal dimensions over the sputtering target.

10. The apparatus of claim 1, wherein the distance between the edge of the magnetron and the edge of the grounded shield is greater than 50 mm.

11. The apparatus of claim 10, wherein the distance between the edge of the magnetron and the edge of the grounded shield is greater than 100 mm.

12. An apparatus for sputtering materials on rectangular substrates at a voltage less than 400 volts, comprising:
a sputtering target; wherein the target is biased at a voltage less than 400 volts during sputtering materials on the rectangular substrates;
a grounded shield surrounding the sputtering target, wherein the shortest distance between the grounded shield and the sputtering target is less than the plasma dark space thickness;
a magnetron in the back of the sputtering target, where in the edge of the magnetron does not overlap the grounded shield; and
an antenna structure placed between the sputtering target and the substrate, wherein the antenna structure is grounded during sputtering.

13. The apparatus of claim 12, wherein the target is biased at a voltage equaling to or less than 350 volts during sputtering.

14. The apparatus of claim 12, wherein the plasma ignition voltage is equaling to or less than 800 volts.

15. The apparatus of claim 12, wherein the sputtering target is made of multiple tiles.

16. The apparatus of claim 12, wherein in the surface areas of the rectangular substrates are greater than 15000 cm².

17. The apparatus of claim 12, wherein the magnetron comprises:
an inner pole having a first magnetic polarity perpendicular to a plane, extending along a single two-ended path in said plane, and including a plurality of straight portions at least some of which separately extend along one rectangular coordinate in a convolute pattern; and
an outer pole having a second magnetic polarity opposite said first magnetic polarity, surrounding said inner pole, and separated therefrom by a separation.

18. The apparatus of claim 12, wherein the magnetron is scanned in two orthogonal dimensions over the sputtering target.

19. The apparatus of claim 12, wherein the distance between the edge of the magnetron and the edge of the grounded shield is greater than 50 mm.

20. The apparatus of claim 12, wherein the antenna of the antenna structure has a width in the range between about 5 mm to about 30 mm and thickness in the range between about 1 mm to about 10 mm.

21. The apparatus of claim 20, wherein the antenna of the antenna structure has a width in the range between about 10 mm to about 20 mm and thickness in the range between about 3 mm to about 7 mm.

22. The apparatus of claim 20, wherein the antenna structure has an opening in the center of the structure.

23. A method of sputtering materials at a voltage less than 400 volts on a rectangular substrate, comprising:
placing the rectangular substrate in a sputtering chamber that has a sputtering target, a grounded shield surrounding the sputtering target, wherein the shortest distance between the grounded shield and the sputtering target is less than the plasma dark space thickness, a magnetron in the back of the sputtering target, where in the edge of the magnetron does not overlap the grounded shield, and an antenna structure placed between the sputtering target and the substrate, wherein the antenna structure is grounded during sputtering;
igniting plasma at a first voltage; and
sputtering materials on the rectangular substrate at a second voltage that is less than 400 volts.

24. The method of claim 23, wherein the second voltage is equal or less than 350 volts during sputtering.

25. The method of claim 23, wherein the first voltage is equal or less than 800 volts.

26. The method of claim 23, wherein the sputtering target is made of multiple tiles.

27. The method of claim 23, wherein in the surface areas of the rectangular substrates are greater than 15000 cm².

28. The method of claim 23, wherein the magnetron comprises:
an inner pole having a first magnetic polarity perpendicular to a plane, extending along a single two-ended path in said plane, and including a plurality of straight portions at least some of which separately extend along one rectangular coordinate in a convolute pattern; and
an outer pole having a second magnetic polarity opposite said first magnetic polarity, surrounding said inner pole, and separated therefrom by a separation.

29. The method of claim 23, wherein the magnetron is scanned in two orthogonal dimensions over the sputtering target.

30. The method of claim 23, wherein the distance between the edge of the magnetron and the edge of the grounded shield is greater than 50 mm.

31. The method of claim 23, wherein the antenna of the antenna structure has a width in the range between about 5 mm to about 30 mm and thickness in the range between about 1 mm to about 10 mm.

32. The method of claim 23, wherein the antenna structure has an opening in the center of the structure
